(19) United States
(12) Patent Application Publication
(10) Pub. No.: US 2023/0105078 A1
(43) Pub. Date: Apr. 6, 2023

(54) OPTOELECTRONIC PRODUCT AND MANUFACTURING METHOD THEREOF

(71) Applicant: EPISTAR CORPORATION, Hsinchu (TW)

(72) Inventors: Min-Hsun HSIEH, Hsinchu (TW); Hsin-Mao LIU, Hsinchu City (TW)

(21) Appl. No.: 17/957,431

(22) Filed: Sep. 30, 2022

Related U.S. Application Data
(60) Provisional application No. 63/252,563, filed on Oct. 5, 2021.

(30) Foreign Application Priority Data
Jun. 16, 2022 (TW) 111122324

(51) Int. Cl. H01L 25/075; H01L 33/00

(52) U.S. Cl. CPC H01L 25/0753; H01L 33/005

(57) ABSTRACT

An LED arrangement method includes providing first LED sections and second LED sections commonly located on a substrate. The first LED sections and the second LED sections are transferred to a bin carrier to form an array of sections having columns and rows. Each of the first LED sections has first LED chips. The first LED chips, as a whole, belong to a first bin. Each of the second LED sections has second LED chips. The second LED chips, as a whole, belong to a second bin. Each of columns has one of the first LED sections and one of the second LED sections. Each of the rows has one of the first LED sections and one of the second LED sections.

### CROSS REFERENCE TO RELATED APPLICATIONS

This application claims the benefit of U.S. Provisional Application Ser. No. 63/252,563, filed Oct. 5, 2021, and claims priority to Taiwan Patent Application No. 111122324 filed on Jun. 16, 2022, which are both incorporated herein by reference in their entirety.

### BACKGROUND

### Technical Field

The present disclosure relates to an optoelectronic product and a manufacturing method therefore, and, in particular, to an optoelectronic product for manufacturing LED display and a manufacturing method therefore.

### Description of the Related Art

A light-emitting diode (LED) is an optoelectronic semiconductor device with characteristics such as low energy consumption, low heat generation, a long operating life, shock resistance, a small size, and fast response speed, and therefore it is suitable for various lighting and display applications.

As breakthroughs continue to improve the technology used in semiconductor processing, the size of LED chips has become smaller than what is visible to the naked eye, e.g., less than 100 μm, 50 μm or 30 μm and the applications for the LED chips are no longer limited to the backlight of LCD displays. The red (R), green (G) and blue (B) LED chips can constitute a pixel, and numerous pixels can constitute an LED display, which means the filters and liquid-crystal layers used in typical displays are no longer required. Since the LED chips are self-illuminating, there is no need for additional backlight modules.

A 4K resolution LED display needs about 24 million LED chips to be installed. The process of transferring and neatly arranging millions or even tens of millions of LED chips from a carrier or a substrate to a display panel is called mass transfer, which requires high accuracy, high yield, and low cost for the production of LED display.

### SUMMARY

An embodiment of the present disclosure provides an LED arrangement method which comprises a step of providing a plurality of first LED sections and a plurality of second LED sections commonly located on a substrate; and a step of transferring the plurality of first LED sections and the plurality of second LED sections to a bin carrier to form an array of sections comprising a plurality of columns and a plurality of rows; wherein each of the plurality of first LED sections comprises a plurality of first LED chips, and the plurality of first LED chips, as a whole, belong to a first bin, wherein each of the plurality of second LED sections comprises a plurality of second LED chips, and the plurality of second LED chips, as a whole, belong to a second bin, wherein each of the plurality of columns comprises one of the plurality of first LED sections and one of the plurality of second LED sections, and wherein each of the plurality of rows comprises one of the plurality of first LED sections and one of the plurality of second LED sections.

### BRIEF DESCRIPTION OF THE DRAWINGS

The present disclosure can be more fully understood by reading the subsequent detailed description and examples with references made to the accompanying drawings, wherein:

FIG. 1 shows a manufacturing method according to an embodiment of the present disclosure.

FIG. 2 shows a growth substrate and exemplary LED sections S1-S6 according to an embodiment of the present disclosure.

FIG. 3 shows an arrangement pattern of the LED sections on the growth substrate according to an embodiment of the present disclosure.

FIG. 4 shows an auxiliary bin carrier disclosed in an embodiment of the present disclosure.

FIG. 5 shows a default bin pattern disclosed in an embodiment of the present disclosure.

FIG. 6 shows a bin carrier produced according to the default bin pattern disclosed in an embodiment of the present disclosure.

FIG. 7A and FIG. 7B show a transferring method disclosed in an embodiment of the present disclosure, illustrating the process of transferring the LED chips from the bin carrier to an auxiliary pixel carrier.

FIG. 8 shows the auxiliary pixel carrier disclosed in an embodiment of the present disclosure.

FIGS. 9A-9C show a pixel carrier having the LEDs of three colors disclosed in an embodiment of the present disclosure.

FIGS. 10-11 show the relationship between the peak wavelength and the position of the LED chips in one sub-row of row Y9 and in one sub-column of column X3 in FIG. 6, respectively.

FIG. 12 shows a cross-sectional view along the midline AA-AA in FIG. 2.

FIGS. 13A-13E show a transferring step disclosed in an embodiment of the present disclosure, illustrating the process of transferring the LED chips to the auxiliary pixel carrier.

FIGS. 14A-14D show a transferring step disclosed in another embodiment of the present disclosure, illustrating the process of transferring the LED chips to the auxiliary pixel carrier.

FIGS. 15A-15D show a processing step disclosed in an embodiment of the present disclosure, illustrating the process of transferring the LED sections to a carrier board.

FIGS. 16A-16D show a processing step disclosed in an embodiment of the present disclosure, illustrating the process of transferring a batch of the LED sections to the bin carrier simultaneously.

FIG. 17 shows a bin pattern 230 disclosed in another embodiment of the present disclosure.

FIG. 18 shows a bin carrier produced according to the bin pattern disclosed in another embodiment of the present disclosure.

FIG. 19A and FIG. 19B show the relationship between the peak wavelength and the position of the LED chips in two rows on a bin carrier according to an embodiment of the present disclosure.

FIG. 20 shows the relationship between a display and the variability σ.

### DETAILED DESCRIPTION

In the following, exemplary embodiments of the present disclosure will be described in detail with reference to the drawings to enable those skilled in the art of the disclosure to fully understand the spirit of the disclosure. The present disclosure is not limited to the following examples but can be implemented in other forms. In this specification, there are identical symbols which denote components having the same or similar structure, function, or principle, and which can be deduced from the teachings of this specification by a person having ordinary skill in the art. In the interest of brevity, the components with the same symbols will not be repeated.

An embodiment of the disclosure provides a bin carrier, on which LED sections are arranged to form an array with rows and columns. Each of the LED sections is assigned to one of the bins according to a test result. Each of the rows on the bin carrier has two or more LED sections belonging to two or more different bins. Each of the columns on the bin carrier has two or more LED sections belonging to two or more different bins. The bin carrier is an optoelectronic product and can be used to manufacture an LED display.

The bin carrier can improve the capacity utilization of the LED chips. On other aspects, the speed of transferring the LED chips can be improved by the methods disclosed in the embodiments of the present disclosure, thereby increasing the production speed of an LED display in mass production.

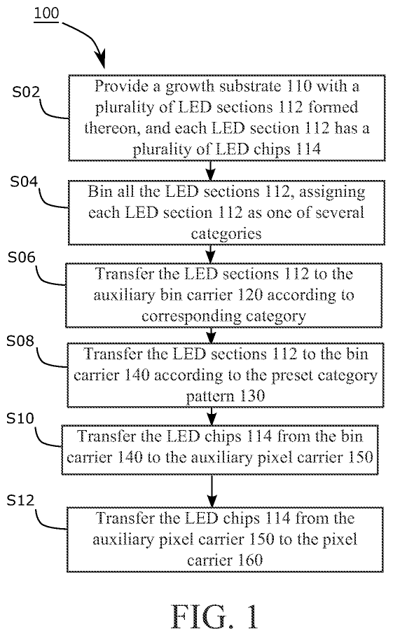

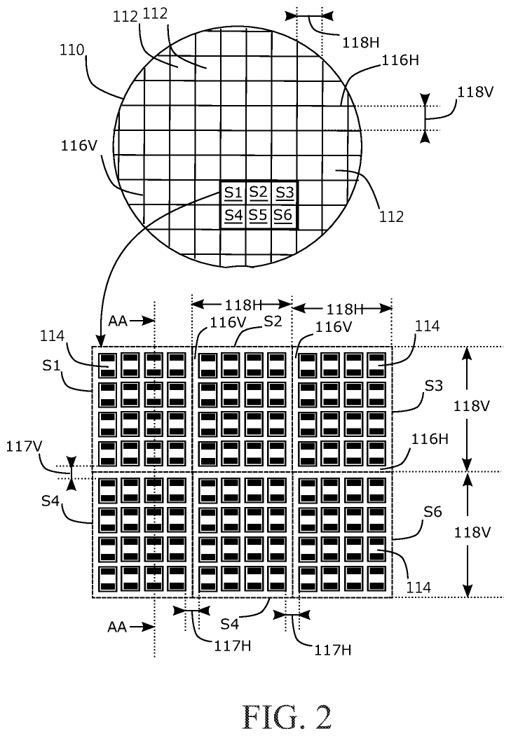

Referring to FIG. 1 with FIG. 2. FIG. 1 discloses the manufacturing method 100 according to one embodiment of the present disclosure, and FIG. 2 shows a growth substrate 110 and six adjacent exemplary LED sections S1-S6 on the growth substrate 110. Although embodiments of the present disclosure are implemented with LED chips, the present disclosure is not limited thereto. In other embodiments, other semiconductor components, such as photodiodes or integrated circuit components may be used for implementation.

In the manufacturing method 100 in FIG. 1, the growth substrate 110 of FIG. 2 is provided in step S02, on which a plurality of LED sections 112 are formed, and each of the plurality of LED sections 112 has a plurality of LED chips 114 with substantially the same optoelectronic properties and the same size. For example, each of the LED sections S1-S6 has 4λ4 LED chips 114 formed on the growth substrate 110 and arranged in an array. Although the number of the LED chips 114 in the embodiments of the disclosure is 16 (4×4), the disclosure is not limited to thereto. In one embodiment, the area of each LED sections S1-S6 is smaller than 100 mm² (10 mm×10 mm), for example, between 4 mm²(2 mm×2 mm) and 36 mm² (6 mm×6 mm), or between 25 mm² (5 mm×5 mm) and 64 (8 mm×8 mm).

The LED chip 114 includes a first semiconductor layer (not shown), an active layer (not shown), and a second semiconductor layer (not shown). The first semiconductor layer and the second semiconductor layer can provide electrons and holes respectively, and the electrons and the holes recombine in the active layer to emit light. The first semiconductor layer, the active layer and the second semiconductor layer may include III-V semiconductor, such as AlₓInyGa_{(1-x-y)}N or AlₓInyGa_{(1-x-y)}P, wherein 0≤x, y≤1, and (x+y)≤1. Depending on the material of the active layer, the LED chips may emit red light with peak wavelength between 610 nm and 650 nm, green light with peak wavelength between 530 nm and 570 nm, cyan light with peak wavelength between 500 nm and 485 nm, blue light with peak wavelength between 450 nm and 490 nm, violet light with peak wavelength between 400 nm and 450 nm, or ultraviolet light with peak wavelength between 280 nm and 400 nm.

The material of growth substrate may be germanium (Ge), gallium arsenide (GaAs), indium phosphorus (InP), silicon (Si), glass, Sapphire, silicon carbide (SiC), lithium aluminate (LiAlO₂), zinc oxide (ZnO), gallium nitride (GaN), aluminum nitride (AlN), etc. Between two adjacent LED sections 112, there are horizontal scribe line (or referred to as horizontal border line) 116H and vertical scribe line (or referred to as vertical border line) 116V. The horizontal scribe line 116H has a scribe line width 117V. The vertical scribe line 116V has a scribe line width 117H.

The growth substrate 110 has vertical section pitches 118V and horizontal section pitches 118H. The vertical section pitch 118V is the vertical length of an LED section 112, as shown in FIG. 2. Also, the vertical section pitch 118V may be the distance between the center horizontal line of one LED section 112 to the center horizontal line of another up or down adjacent LED section 112. The vertical section pitch 118V may be the distance between the top left corner of one LED section 112 to the top left corner of another up or down adjacent LED section 112. The vertical section pitch 118V may also be the distance between the center lines of two adjacent horizontal scribe lines 116H in FIG. 2. Similarly, the horizontal section pitch 118H refers to the horizontal width of an LED section 112, and the horizontal section pitch 118H may be the distance between the center lines of two adjacent vertical scribe lines 116V.

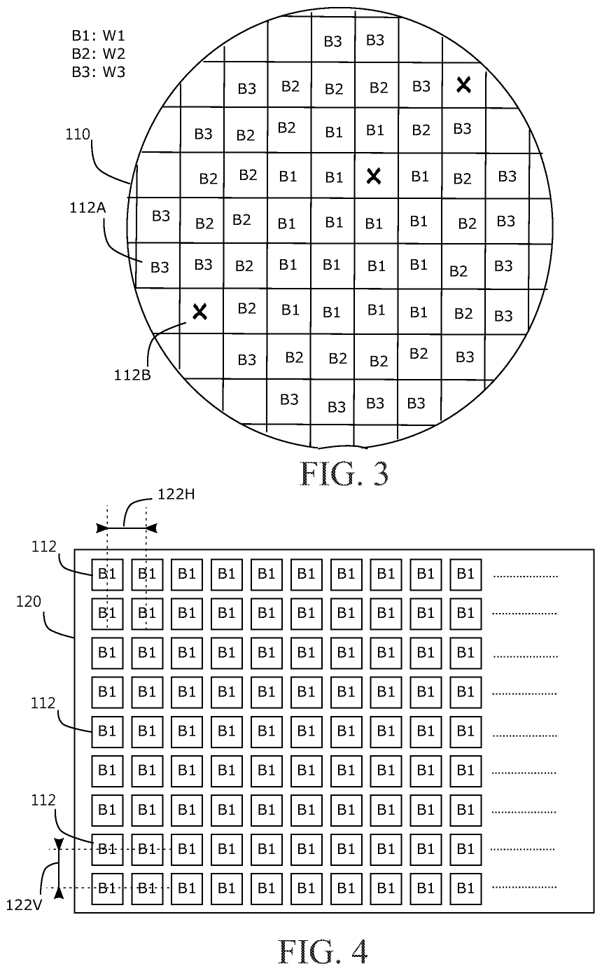

These LED sections 112 are binned in step S04 of FIG. 1, and each LED section 112 is assigned to one of several bins. For example, automatic optical inspection (AOI), photoluminescence (PL), electroluminescence (EL), or the combination thereof is performed on all of the LED chips 114 in each of the LED sections 112. In other embodiments, in order to improve the test efficiency, the LED chips 114 in each of the LED sections 112 are sampled for electroluminescence (EL) test, for instance, only 5%, 10%, or 30% of the LED chips 114 in one LED section 112 are subjected to EL test. The bin may be determined by one of the overall optoelectronic properties of the LED chips 114 in one LED section 112. For example, the optoelectronic property may be, but not limited to peak or dominant wavelength, illuminance intensity level, chromaticity scale, or the combination thereof. FIG. 3 illustrates the binning results of the LED sections 112 on the growth substrate, wherein three bins “B1”, “B2”, and “B3” indicate that the median or average of the peak wavelengths of all or part of the LED chips 114 in one of the LED sections 112 are W1, W2, and W3, respectively. Another bin “X” indicates that the optoelectronic property or appearance of an LED section does not meet the manufacturing specification so such LED section should be picked out. The optoelectronic property may be forward voltage, reverse voltage, illuminance intensity level, or peak wavelength. For example, the LED section 112A is assigned to the bin “B3”, indicating the peak wavelengths of the LED chips 114 in the LED section 112A are approximately around W3, and the average value of the peak wavelengths is approximately W3. The LED section 112B is assigned to bin “X”, indicating that the tested characteristic optoelectronic or the appearance of the LED section 112B does not meet manufacturing specifications. For example, there are too many LED chips 114 regarded as invalid or defective because their AOI, PL, EL test results in the LED section 112B do not meet the manufacturing specifications. Or, there are too many LED chips 114 whose wavelengths do not fall within the range of the binning. In the LED section 112A, there may be one or two specific LED chips 114 whose peak wavelengths are quite different from other LED chips 114 in the same LED section 112 due to the variation in manufacturing process. However, it does not affect the peak wavelength bin of this LED section 112, because the peak wavelength bin is determined by the average value of the peak wavelengths of all LED chips 114 in the LED section 112.

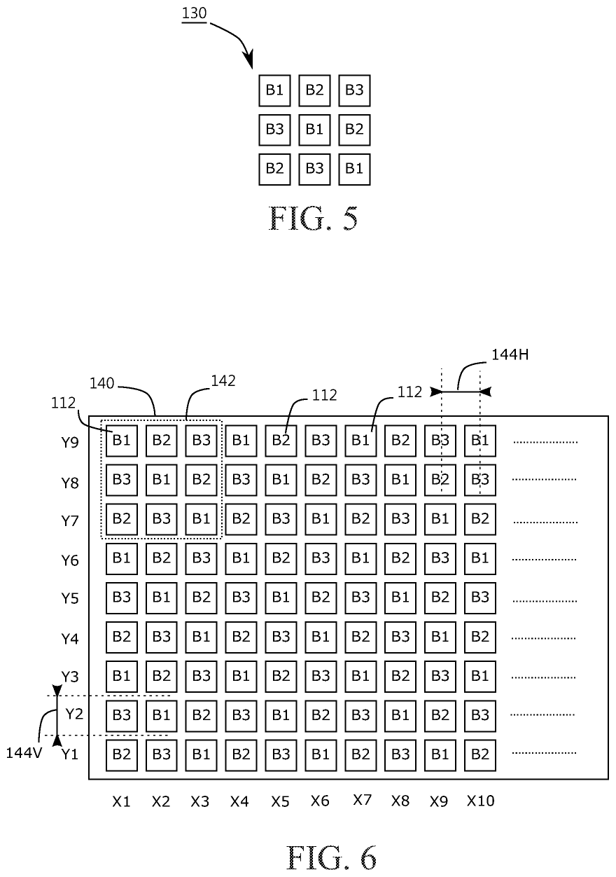

Referring to FIG. 1 and FIG. 4. These LED sections 112 are transferred to an auxiliary bin carrier 120 to form an array of sections according to the corresponding bin. The array of sections includes a plurality of LED sections 112 arranged as array on the auxiliary bin carrier 120. Each auxiliary bin carrier 120 only has multiple LED sections 112 in the same bin. For example, the LED sections 112 assigned to bin “B1”, “B2” and “B3” on the growth substrate 140 are respectively transferred to three different auxiliary bin carriers 120. In step S06, one LED section 112 or multiple LED sections 112 in the same bin can be transferred at one time. FIG. 4 illustrates a plurality of LED sections 112 assigned to bin “B1” is disposed on and arranged in array on the auxiliary bin carrier 120 to form an array of sections. The material of auxiliary bin carrier 120 may be silicon, glass, sapphire, silicon carbide, thermal release tape, UV release tape, chemical release tape, heat resistant tape, Blue Tape, or the tape with a dielectric release layer. The transferring tool may include pick-and-place head, stamp, roller, vacuum head, magnetic head, laser lift-off, laser ablation, or the combination thereof.

FIG. 4 also shows the vertical section pitch 122V and the horizontal section pitch 122H on the auxiliary bin carrier 120. The vertical section pitch 122V is the distance between the center horizontal line of one LED section 112 and the center horizontal line of another up or down adjacent LED section 112 on the auxiliary bin carrier 120. The horizontal section pitch 112H is the distance between the center vertical line of one LED section 112 and the center vertical line of another left or right adjacent LED section 112 on the auxiliary bin carrier 120. The vertical section pitch 112V in FIG. 4 may be the same as or different from the vertical section pitch 118V in FIG. 2. Similarly, the horizontal section pitch 112H in FIG. 4 may be the same as or different from the horizontal pitch section 118H in FIG. 2.

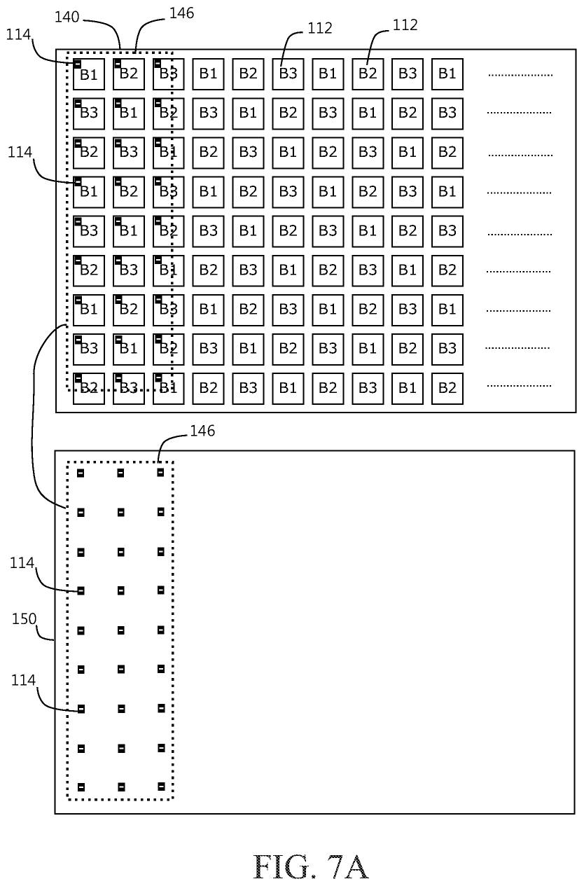

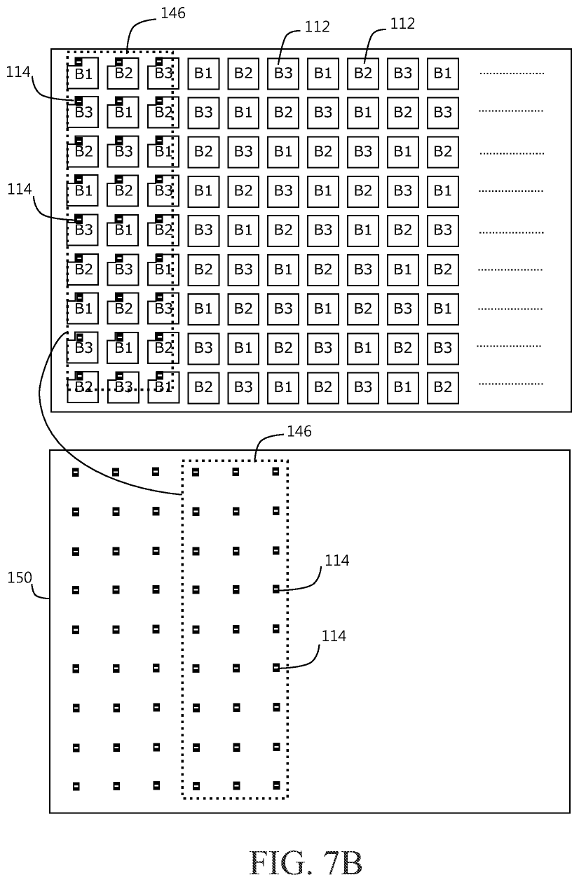

Referring to FIG. 1, FIG. 5 and FIG. 6. FIG. 5 shows an array of sections with a default bin pattern 130, and FIG. 6 shows a bin carrier 140 produced according to the default bin pattern 130. As shown in step S08 of FIG. 1, the LED sections 112 of different bins are transferred from multiple auxiliary bin carriers 120 to one bin carrier 140 according to the default bin pattern 130 of FIG. 5. According to an embodiment, the default bin pattern 130 of FIG. 5 shows an example of a 3×3 array of sections with a fixed arrangement rule, and each column and each row independently have LED sections assigned to bin B1, bin B2, and bin B3. The number and the arrangement of the bin patterns in this embodiment are merely an example, and the present disclosure is not limited thereto. The array of sections on the bin barrier 140 in FIG. 6 is produced according to the bin pattern 130, and the LED sections 112 thereon are arranged in several rows (such as row Y1, Y2 . . . ) and several columns (such as column X1, X2 . . . ). The default bin pattern 130 is replicated on the bin carrier 140. For example, the nine LED sections 112 in the upper left area 142 present the default bin pattern 130 in FIG. 5. Each column and each row of the bin carrier 140 in FIG. 6 has LED sections 112 of more than two bins. Each column includes LED section assigned to bin B1 and LED section assigned to bin B2. Each row includes LED section assigned to bin B1 and LED section assigned to bin B2. The material of the bin carrier 140 may also be silicon, glass, sapphire, silicon carbide, thermal release tape, UV release tape, chemical release tape, heat resistant tape, the tape with a dielectric release layer, or Blue Tape.

The default bin pattern 130 only rules the arrangement between the LED sections 112, and does not rule the distance between the LED sections 112. In other words, the distance between the LED sections 112 on the bin carrier 140 in FIG. 6 does not necessarily be the same as the distance between the LED sections in the default bin pattern 130. FIG. 6 also shows the vertical section pitch 144V and the horizontal section pitch 144H on the bin carrier 140.

It can be seen from the default bin pattern 130 of FIG. 5 that, in each row and each column of the array of sections on the bin carrier 140 of FIG. 6, the number of LED sections 112 of bin B1, the number of LED sections 112 of bin B2, and the number of LED sections 112 of bin B3 are about the same, which means that the ratio between them is about 1:1:1. The ratio provided in this embodiment is merely an example, and the present disclosure is not limited thereto, except that the value of the ratio must be a positive integer. For example, the number of LED sections 112 of bin B1: the number of LED sections 112 of bin B2: the number of LED sections 112 of bin B3 may be 1:2:3, 1:3:5, 1:5:7, or another ratio that is practically reasonable.

In step S08, one LED section 112 or a plurality of LED sections 112 of the same bin may be transferred at the same time.

In an embodiment, as shown in FIG. 1, step S08 follows step S06. The LED sections 112 of the same bin on the bin carrier 140 in FIG. 6 are transferred from a single auxiliary bin carrier 120. For example, all the LED sections 112 of bin B1 in FIG. 6 are transferred from one auxiliary bin carrier 120 with the LED sections 112 of only bin B1. Similarly, all the LED sections 112 of bin B2 in FIG. 6 are transferred from one auxiliary bin carrier 120 with the LED sections 112 of only bin B2. In another embodiment, step S06 can be omitted, and step S08 follows step S04, which means that all of the LED sections 112 in FIG. 6 are directly transferred from the growth substrate 110 without being transferred to the auxiliary bin carrier 120 in advance.

In one embodiment, the bin carrier 140 in FIG. 6 may be subsequently inspected and repaired to improve the yield of each of the LED sections 112 on the bin carrier 140. For example, electroluminescence test is performed on all of the LED chips 114 on the bin carrier 140, and the LED chips 114 which do not meet the predetermined specification are repaired or replaced so that generally the LED chips 114 in each of the LED sections 112 on the bin carrier 140 can meet the specification.

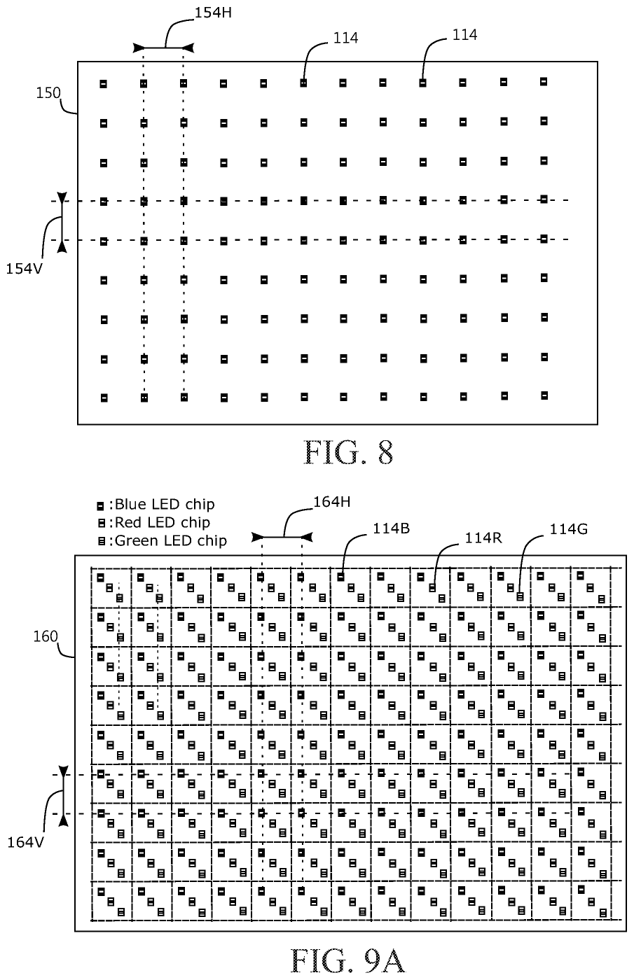

Referring to FIG. 1 and FIGS. 7A-7B. As shown in FIG. 1, step S10 follows step S08, wherein partial of the LED chips 114 are selected and transferred from the bin carrier 140 to an auxiliary pixel carrier 150. FIG. 7A and FIG. 7B show the process of transferring the LED chips 114 from the bin carrier 140 to the auxiliary pixel carrier 150 according to one embodiment. FIG. 7A shows a batch of LED chips (including a plurality of LED chips 114) are picked up at one time by the pick-and-place head 146 and placed on the auxiliary pixel carrier 150, wherein each of the LED chips 114 is in the m-th row and the n-th column (such as the first row and the first column) of the corresponding LED section 112, and both m and n are positive integers. In other words, the pick-and-place head 146 is able to pick up the LED chips 114 at a predetermined position in each of the LED sections 112.

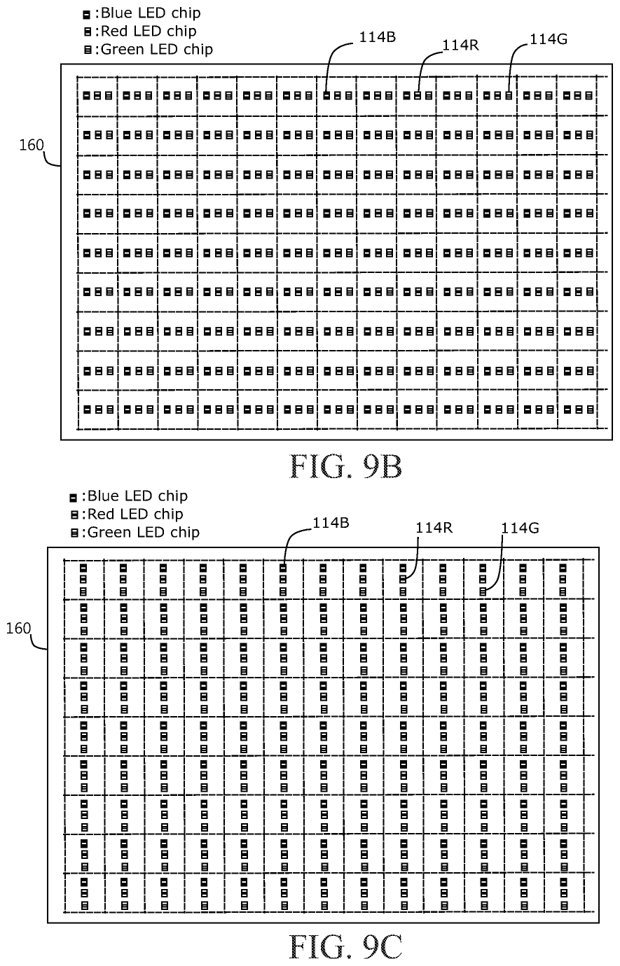

The bin carrier 140 in FIG. 7B shows that the first batch of LED chips 114 has been transferred at one time, and another batch of LED chips, which includes the LED chips 114 from the same location (such as in the first row and the second column) of the multiple LED sections 112, is picked up by the pick-and-place head 146 and placed on the auxiliary pixel carrier 150 adjacent to the previously placed the first LED chips 114 of the first batch. FIG. 7B also shows that several batches of the LED chips 114 are arranged on the auxiliary pixel carrier 150 along a predetermined direction. In other words, after the first batch of the LED chips 114 being placed on the auxiliary pixel carrier 150, the next batch of the LED chips 114 are moved by a predetermined distance relative to the first batch of the LED chips 114 and then placed on the auxiliary pixel carrier 150 after being displaced. As shown in FIG. 7B, several batches of the LED chips 114 are arranged on the auxiliary pixel carrier 150 from left to right, but the present disclosure is not limited thereto. In other embodiments, several batches of the LED chips 114 are arranged on the auxiliary pixel carrier 150 from right to left, from top to bottom, or from bottom to top. Finally, the LED chips 114 arranged in array are formed on the auxiliary pixel carrier 150, as shown in FIG. 8, and the gap between the adjacent LED chips 114 is larger than that on the bin carrier 140. The auxiliary pixel carrier 150 may be silicon, glass, sapphire, silicon carbide, thermal release tape, UV release tape, chemical release tape, heat resistant tape, the tape with a dielectric release layer, or Blue Tape. Each of the LED chips 114 corresponds to a subpixel of a pixel in a display.

FIG. 8 shows the auxiliary pixel carrier 150 with same color LED chips 114, wherein the array on the auxiliary pixel carrier 150 has a vertical pixel pitch 154V and a horizontal pixel pitch 154H. The vertical pixel pitch 154V in FIG. 8 equals to the vertical section pitch 144V in FIG. 6. In some embodiments, the vertical pixel pitch 154V does not equal to the vertical section pitch 122V in FIG. 4. Similarly, the horizontal pixel pitch 154H in FIG. 8 equals to the horizontal section pitch 144H in FIG. 6. In some embodiments, the horizontal pixel pitch 154H does not equal to the horizontal section pitch 122H in FIG. 4. The vertical pixel pitch 154V and the horizontal pixel 154H equal to the pixel pitch of the display.

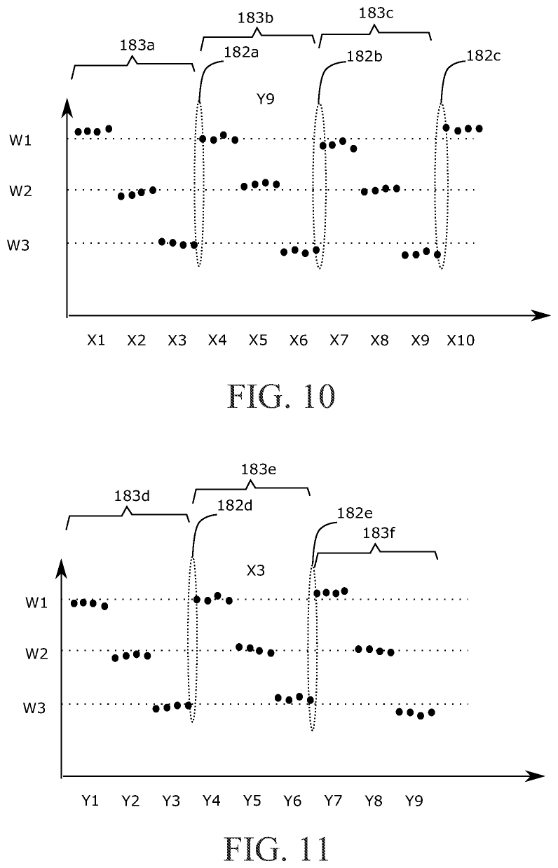

Referring to FIG. 1 and FIG. 9A. As shown in FIG. 1, step S12 follows steps S10, wherein partial LED chips 114 are selected and transferred from the auxiliary pixel carrier 150 to a pixel carrier 160. FIG. 9A shows the pixel carrier 160 implemented in accordance with an embodiment of the present disclosure. The pixel carrier 160 has an array formed by a plurality of pixel, and each of the plurality of pixel has a blue LED chip 114B, a red LED chip 114R, and a green LED chip 114G. A batch of the blue LED chips 114B can be transferred at one time from the auxiliary pixel carrier 150 having only the blue LED chips 114B, and the vertical pixel pitch 164V and the horizontal pixel pitch 164H are respectively the same with the vertical pixel pitch 154V and the horizontal pixel pitch 154H of the auxiliary pixel carrier 150. A batch of the green LED chips 114G can transferred at one time from the auxiliary pixel carrier 150 having only the green LED chips 114G, and the vertical pixel pitch 164V and the horizontal pixel pitch 164H are respectively the same with the vertical pixel pitch 154V and the horizontal pixel pitch 154H of the auxiliary pixel carrier 150. A batch of the red LED chips 114R can be transferred at one time from the auxiliary pixel carrier 150 having only the red LED chips 114R, and the vertical pixel pitch 164V and the horizontal pixel pitch 164H are respectively the same with the vertical pixel pitch 154V and the horizontal pixel pitch 154H of the auxiliary pixel carrier 150. In another embodiment, referring to FIG. 1, the pixel carrier 160 can be manufactured with step S12 following step S08 of without step S10. For example, as described above, a batch of the blue LED chips 114B can be transferred at one time from the bin carrier 140 having only the blue LED chips 114B, a batch of the green LED chips 114G can be transferred at one time from the bin carrier 140 having only the green LED chips 114G, and a batch of the red LED chips 114R can be transferred at one time from the bin carrier 140 having only the red LED chips 114R. The vertical pixel pitch 164V and the horizontal pixel pitch 164H in FIG. 9A are the same as the vertical section pitch 144V and the horizontal section pitch 144H in FIG. 6, respectively. The vertical pixel pitch 164V and the horizontal pixel pitch 164H equal to the pixel pitch of the display. The pixel carrier 160 may be a circuit board with conduction lines, a TFT substrate, a substrate with a redistribution layer (RDL), or a substrate for a pixel package used in a display. Each of the LED chips 114 corresponds to a subpixel of a pixel of a display. In one embodiment, the display is assembled of several pixel carriers 160, and the LED chips on each of the pixel carriers 160 may come from different growth substrates. Although a single pixel carrier 160 in FIG. 8 has the LED chips 114 of different bins distributed thereon, when multiple pixel carriers 160 are assembled into a display through the aforementioned steps, the quantity ratio and/or arrangement of LED chips 114 on different pixel carriers 160 are all the same. For example, they are the same as the default bin pattern 130. In this way, different pixel carriers 160 present consistent or similar visual effects so there is no color or brightness differences at the junctions between the pixel carriers 160. Therefore, the display can present a uniform image.

As shown in FIG. 9A, in each pixel, the blue LED chip 114B, the red LED chip 114R, and the green LED chip 114G are arranged in a diagonal line. For example, the blue LED chip 114B, the red LED chip 114R, and the green LED chip 114G are arranged sequentially from top left to bottom right (or in reverse direction), but the present disclosure is not limited thereto. FIGS. 9B and 9C respectively illustrate two pixel carriers 160 according to other embodiments, in which the blue LED chip 114B, the red LED chip 114R, and the green LED chip 114G are arranged in a horizontal line and a vertical line, respectively. For example, in FIG. 9B, the blue LED chip 114B, the red LED chip 114R, and the green LED chip 114G are arranged sequentially from left to right (or in reverse direction), and in FIG. 9C, the blue LED chip 114B, the red LED chip 114R, and the green LED chip 114G are arranged sequentially from top to bottom (or in reverse direction).

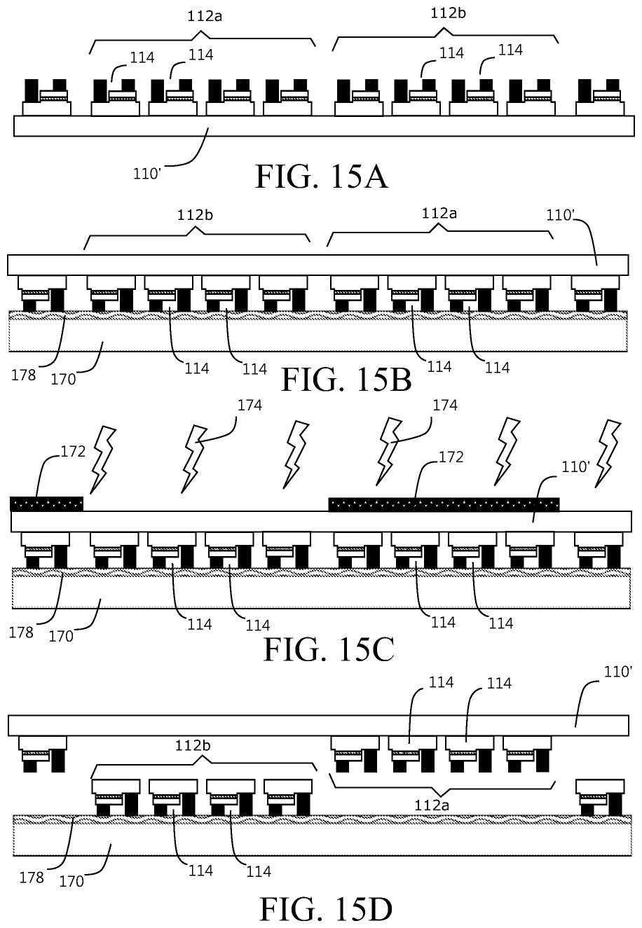

In one embodiment, as shown in FIG. 13B, two electrodes 113 on each of the LED chips 114 have a solder material thereon, and the solder material may be a low temperature solder material, including tin (Sn) and/or bismuth (Bi). When the LED chips are bonded to electrode pads in a display or in a package subsequently, a low-temperature bonding process can be performed. In this way, the poor bonding caused by mismatch of the coefficient of thermal expansion (CTE) between the LED chips and the display or the package in high-temperature bonding process can be avoided.

The manufacturing method 100 disclosed in FIG. 1 and the bin carrier 140 disclosed in FIG. 6 can increase the capacity utilization of LED chips. The bin carrier 140 can combine the LED sections 112 of different bins and apply them to form a display. This method can avoid using LED chips of a single bin and prevent LED chips of specific bin, which are not selected for forming a display, from being discarded or turning into inventory for the manufacturer. In other words, with a few exceptions (e.g., irregularities and malfunctions), LED chips dispersed in various bins can be used in the displays. For example, as shown in FIG. 3, largest number of LED sections 112 of bin B1 are distributed mainly in the middle area of the growth substrate 110. If a pixel carrier is only allowed to adopt the LED chips 114 in the LED sections 112 of bin B1, the LED sections 112 of bins B2 and B3 cannot be used, and the overall capacity utilization of LED chips is reduced.

The bin carrier 140 makes the auxiliary pixel carrier 150 or the pixel carrier 160 to be produced quickly. As shown in FIGS. 7A-7B and FIG. 9A, A batch of the LED chips 114 on the bin carrier 140 can be transferred at one time to the auxiliary pixel carrier 150 or the pixel carrier 160. As long as the pick-and-place head 146 in FIG. 7A and FIG. 7B can pick up sufficient number of LED chips 114 at a time, the auxiliary pixel carrier 150 or pixel carrier 160 can be produced quickly.

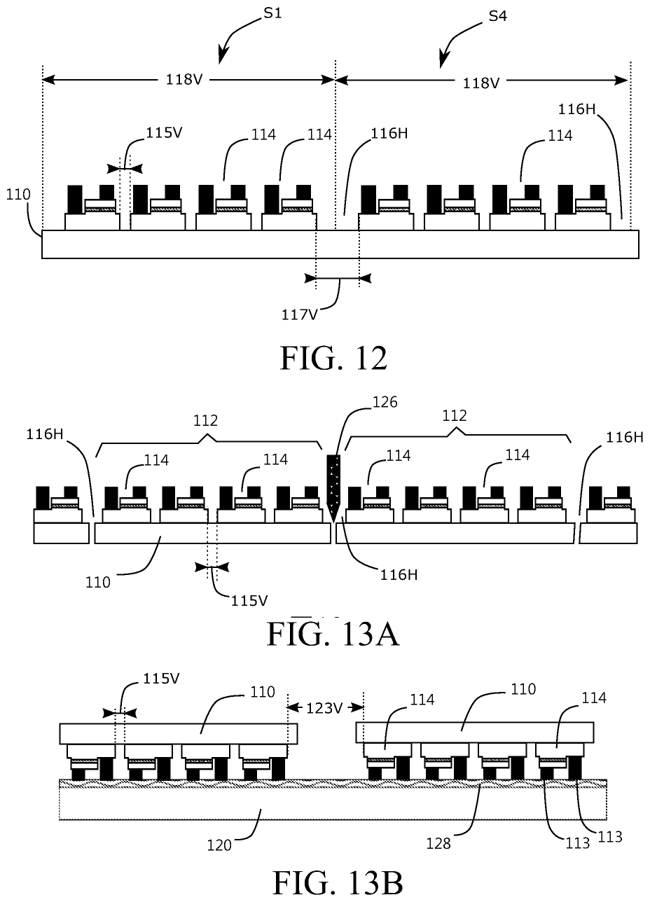

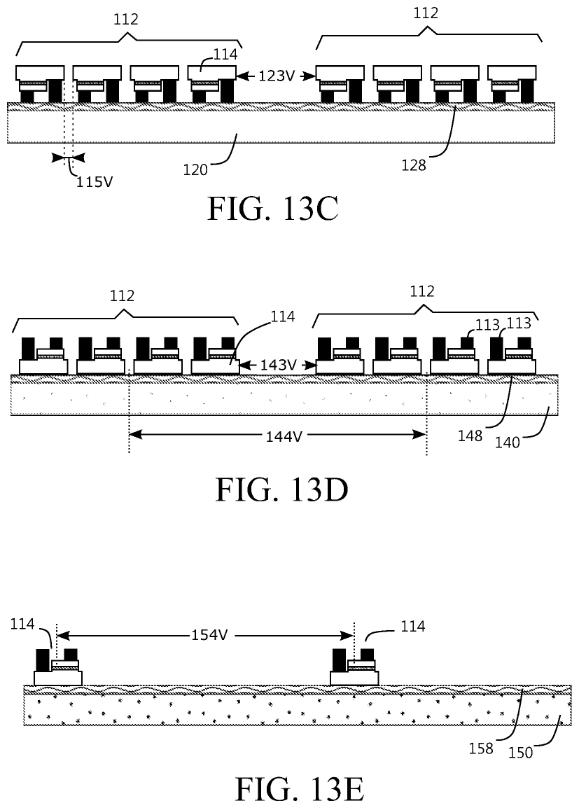

FIG. 10 and FIG. 11 respectively show the characteristic distribution curve of the LED chips 114 in one sub-row of row Y9 of LED sections in FIG. 6, and the characteristic distribution curve of the LED chips 114 in one sub-column of column X3. In one embodiment, the characteristic distribution curve represents the relation between peak wavelength and location. In the following, section BL (YA, XA) represents the LED section 112 being located in the section row YA and the section column XA of the bin carrier 140 in FIG. 6. As shown in FIG. 6, each of the LED sections 112 is binned according to the peak wavelength bin. The peak wavelength bin referred to herein may be the median or average of peak wavelengths of all or some of the LED chips 114 in one LED section 112. The bin of section BL (Y9, X1) in FIG. 6 is “B1”, which means the median or average of the peak wavelengths of all or some of the LED chips 114 in section BL (Y9, X1) is W1, and so the peak wavelength bin of section BL (Y9, X1) is W1. Similarly, the peak wavelength bin of section BL (Y9, X2) is W2, and so forth. FIG. 10 shows the distribution relationship between the peak wavelengths and the position of the LED chips 114 in section row Y9 of the bin carrier 140 in FIG. 6. The black dot in the figure represents one LED chip 114, and the pattern and the number of LED chips 114 shown in the distribution relationship are merely for illustration or simplification, and not intended to limit the scope of the present disclosure. Each of the LED section 112 in FIG. 6 has a plurality of sub-rows and sub-columns composed of LED chips 114. For example, referring to FIG. 2, the section 51 includes 4 sub-columns and 4 sub-rows, and each sub-column includes 4 LED chips 114, and each sub-row includes 4 LED chips 114. As shown in FIG. 10, the peak wavelength of the LED chips 114 in certain sub-rows of section row Y9 in FIG. 6 can be changed regularly according to the physical position of the LED section 112 to which the LED chip 114 belongs. This regular change can be visually expressed as a repetitive stair-like pattern, and the smallest unit pattern of the stair-like pattern may be ascending stair-like (from bottom left to top right), descending stair-like (from top left to bottom right), or a combination thereof. For example, FIG. 10 shows a stair-like pattern including a repetitive descending stair-like patterns, which means the LED chips 114 in the section column X1 belong to the same peak wavelength bin. Similarly, in the section column X2-X10, the LED chips 114 also belong to the same peak wavelength bin, respectively. The range of the wavelength variation of LED chips 114 in a single peak wavelength bin is about ±A %, e.g., A=5, 10, or 15. There may be discontinuous wavelength changes between section BL (Y9, X1) and section BL (Y9, X2), and between section BL (Y9, X2) and section BL (Y9, X3). The range of the discontinuous wavelength change is about ±B %, and B is about 2, 3, 4, 5, and 6 times of A. The range of the wavelength change here refers to the percentage of the absolute value of the wavelength difference between two adjacent LED chips 114 to the wavelength of the first LED chip.

Section BL (Y9, X1), section BL (Y9, X2) and section BL (Y9, X3) together represent the first wavelength distribution section 183a. Similarly, section BL (Y9, X4), section BL (Y9, X5) and section BL (Y9, X6) together represent the second distribution section 1863b, and the distribution pattern of the second distribution section 1863b is similar to that of the first distribution section 183a. Section BL (Y9, X7), section BL (Y9, X8) and section BL (Y9, X9) together represent the third distribution section 183c, and the distribution pattern of the third distribution section 183c is similar to that of the first distribution section 183a and that of the second distribution section 183b. Taking FIG. 10 as an example, there are relatively obvious discontinuous wavelength changes 182a, 182b and 182c between the junctions of different wavelength distribution sections, i.e., between section BL (Y9, X3) and section BL (Y9, X4), between section BL (Y9, X6) and section BL (Y9, X7), and between section BL (Y9, X9) and section BL (Y9, X10). In other words, the wavelength distribution of the LED chips in any sub-row on the bin carrier 140 has a plurality of similar wavelength distribution sections, and a single wavelength distribution section has a plurality of discontinuous wavelength distributions (i.e., transition area of different peak wavelengths bin).

FIG. 11 shows the relation between one of the peak wavelengths and the location of LED chips of section column X3 in the bin carrier 140 of FIG. 6. FIG. 11 shows the LED chips 114 of the section row Y1 belonging to a single peak wavelength bin W1. Similarly, the LED chips 114 of row Y2-Y9 also respectively belong to a single peak emission bin. The range of the wavelength variation of LED chips 114 in a single peak wavelength bin is about ±A %, e.g., A=5, 10, or 15. There may be discontinuous wavelength changes between section BL (Y1, X3) and section BL (Y2, X3), and between section BL (Y2, X3) and section BL (Y3, X3). The range of the discontinuous wavelength change is about ±B %, and B is about 2, 3, 4, 5, and 6 times of A. Section BL (Y1, X3), section BL (Y2, X3) and section BL (Y3, X3) together represent the fourth wavelength distribution section 183d. Similarly, section BL (Y4, X3), section BL (Y5, X3) and section BL (Y6, X3) together represent the fifth distribution section 1863e, and the distribution pattern of the fifth distribution section 1863e is similar to that of the fourth distribution section 183d. Section BL (Y7, X3), section BL (Y8, X3) and section BL (Y9, X3) together represent the sixth distribution section 1863f, and the distribution pattern of the sixth distribution section 1863f is similar to that of the fourth distribution section 183d and that of the fifth distribution section 183e. Take FIG. 11 as an example, there are relatively obvious discontinuous wavelength changes 182d, and 182e between the junctions of different wavelength distribution sections, i.e., between section BL (Y3, X3) and section BL (Y4, X3), and between section BL (Y6, X3) and section BL (Y7, X3). In other words, the wavelength distribution of the LED chips 114 in any column on the bin carrier 140 has a plurality of similar wavelength distribution sections, and a single wavelength distribution section has a plurality of discontinuous wavelength distributions (i.e., transition area of different peak wavelengths bin).

The distribution of the peak wavelength of the LED chips 114 in any column and any row of the bin carrier 140 in FIG. 6 are repeating discontinuous, as shown as the wavelength changes 182a-182e in FIG. 10 and FIG. 11, respectively. This indicates that the LED chips 114 on the bin carrier 140 are formed according to the default bin pattern 130 in FIG. 5, and also indicates that every column and every row of the bin carrier 140 have at least LED sections 112 of two bins.

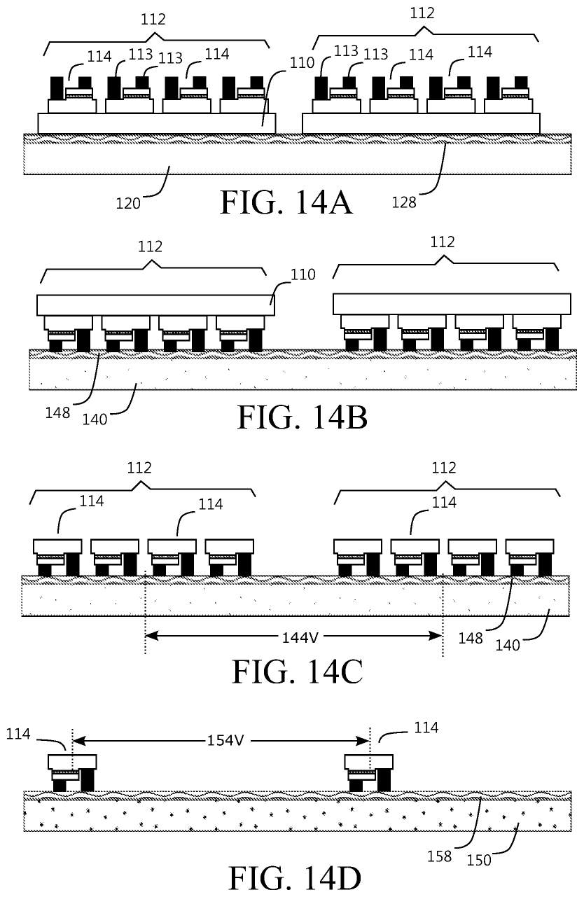

Referring to FIG. 2 and FIG. 12, FIG. 12 is the cross-sectional view of FIG. 2 along the midline AA-AA, wherein 4 LED chips 114 belong to LED section S1 and other 4 LED chips 114 belong to LED section S4, and these eight LED chips 114 are all formed on the growth substrate 110. FIG. 12 shows the vertical section pitch 118V from the midline of one horizontal scribe line 116H to the midline of another adjacent horizontal scribe line 116. The horizontal scribe line 116H has a scribe line width 117V. A vertical die gap 115V is a distance between two LED chips 114 adjacent to each other in one of the LED sections S1, S4.

FIG. 13A to FIG. 13E are schematic diagrams showing the steps of transferring the LED chips 114 from the growth substrate 110 to the auxiliary pixel carrier 150 according to an embodiment of the present disclosure.

FIG. 13A shows the growth substrate 110 cut by a cutting tool 126 so that the LED sections 112 are separated from each other. After the separation, the LED chips 114 within each LED section 112 remain commonly attached to a single portion of the growth substrate 110. At this point, each LED section 112 is assigned to one of the several bins.

FIG. 13B shows the LED sections 112 of FIG. 13A are adhered to the auxiliary bin carrier 120 by an adhesive layer 128 according to the bin of the LED section after the LED sections 112 being turned upside down. At this time, the LED section 112 still has a single portion of the growth substrate 110. The single portion of the growth substrate 110 is not in contact with the adhesive layer 128 so that the LED chips 114 are bonded on the auxiliary bin carrier 120 with electrodes 113 facing down and in contact with the adhesive layer 128.

FIG. 13C shows that the growth substrate is removed. For example, the laser lift-off technology can be used so that the LED sections 112 in FIG. 13C have only LED chips 114 and no growth substrate 110. FIG. 13C shows a vertical section gap 123V, which is approximately the distance between two adjacent LED chips 114 belonging to two bins of the LED sections 112 in FIG. 13C. The outermost edge of the portion of the growth substrate may still exceed the outermost edge of the outermost LED chip. Therefore, when the LED sections 112 are disposed on the auxiliary bin carrier 120 as shown in FIG. 13B, a vertical section gap 123V is needed to avoid the growth substrates 110 of the adjacent LED sections 112 from colliding with each other. In FIG. 13C, the vertical section gap 123V is greater than the vertical die gap 115V. For example, when the vertical die gap 115V is less than 60 μm, the vertical section gap can be larger than 60 μm to avoid the colliding between the adjacent growth substrates 110 during the process of transferring the adjacent LED sections 112. However, the present disclosure is not limited thereto. In some embodiments, the vertical section gap 123V may be smaller than or equal to the vertical die gap 115V. For example, when the vertical die gap 115V is larger than 60 μm, the vertical section gap 123V may be equal to the vertical die gap 115V.

FIG. 13D shows the bin carrier 140 with LED sections 112 of different bins thereon. The LED sections 112 are transferred from different auxiliary bin carriers 120 respectively according to the default bin pattern 130 of FIG. 5. Comparing with FIG. 13C, the LED sections 112 of FIG. 13D are turned upside down with the electrodes 113 of the LED chips 114 facing up. The LED chips 114 are disposed on and bonded to the bin carrier 140 on opposite side to the electrodes 113 through an adhesive layer 148. FIG. 13D also shows a vertical section gap 143V and the vertical section pitch 144V. The vertical section gap 143V is the distance between two adjacent LED chips 114 belonging to two adjacent LED sections 112 in FIG. 13D. The vertical section pitch 144V is about the same as the distance between the midlines of two adjacent LED sections 112. In some embodiments, the vertical section gap 143V in FIG. 13D is greater than the vertical section gap 123V in FIG. 13C.

In the transferring step disclosed in FIG. 13D, the auxiliary bin carrier 120 disclosed in FIG. 13C is cut by a cutting tool so that all the LED chips 114 in one LED section 112 are located on a single portion of the auxiliary bin carrier 120. The bin carrier 120 is then turned over with the LED sections 112 thereon, and is adhered to the bin carrier 140 through the adhesive layer 148. Then, the auxiliary bin carrier 120 is removed from the LED sections 112, as the result shown in FIG. 13D.

FIG. 13E shows two LED chips 114 on the auxiliary pixel carrier 150. The two LED chips 114 may be transferred from two adjacent LED sections 112 in FIG. 13 respectively, and disposed on and bond to the auxiliary pixel carrier 150. In one embodiment, the distance between the midlines of the two adjacent LED chips 114 in FIG. 13E, i.e., the vertical pixel pitch 154V equals to the vertical section pitch 144V in FIG. 13D. In another embodiment, the auxiliary pixel carrier 150 may be replaced with the above-mentioned pixel carrier 160. In the other word, the LED chips 114 may be transferred from the bin carrier 140 to the pixel carrier 160 directly.

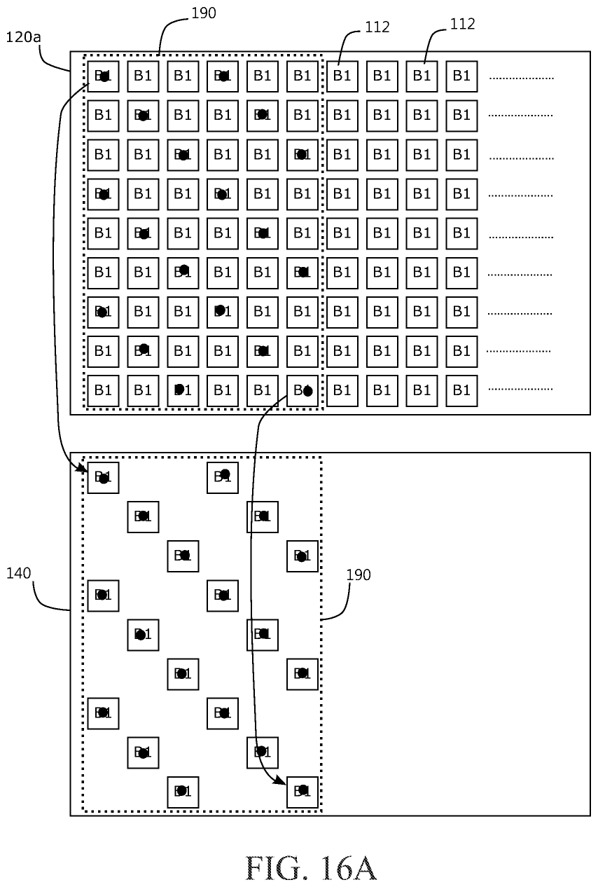

The transferring shown in FIG. 13A to FIG. 13E is merely an example of the present disclosure, and is not intended to limit the present disclosure. FIG. 14A to FIG. 14D shows another process of transferring the LED chips 114 from the growth substrate 110 to the auxiliary pixel carrier 150.

Following FIG. 13A, FIG. 14A shows the LED sections 112 are separated and bonded to the bin carrier 120 with the electrodes 113 of the LED chips 114 facing up and the growth substrate 110 in contact with the adhesive layer 128. For example, one of the LED sections 112 in FIG. 13A is picked up, and placed and bond to the adhesive layer 128 of the auxiliary bin carrier 120. Each auxiliary bin carrier 120 only has the LED sections 112 of one bin. The relation between the vertical section gap and the vertical die gap on the auxiliary bin carrier 120 is similar with that in FIG. 13B and FIG. 13C and not repeated here.

Following FIG. 14A, FIG. 14B shows that the LED sections 112 from the auxiliary bin carriers 120 of different bins are transferred to the bin carrier 140 according to the default bin pattern 130 of FIG. 5. Comparing to FIG. 14A, the LED sections in FIG. 14B remain attached to the growth substrate 110 but are turned upside down. The LED sections 112 are disposed on the bin carrier 140 through the adhesive layer 148.

FIG. 14C shows the growth substrate 110 in FIG. 14B is removed, and only the LED chips 114 are left on the bin carrier 140. For example, the growth substrate 110 is removed by laser lift-off so that the growth substrate 110 in FIG. 14B is removed from the LED chips 114. The relation between the vertical section gap and the vertical die gap on the bin carrier 140 is similar to that in FIG. 13D above and not repeated here.

FIG. 14D shows two chips 114 on the auxiliary pixel carrier 150, which may be transferred from the two adjacent LED sections 112 in FIG. 14C respectively and disposed on an adhesive layer 158. In one embodiment, the vertical pixel pitch 154V in FIG. 14D is equal to the vertical section pitch 144V in FIG. 14C. In another embodiment, the auxiliary pixel carrier 150 can be replaced with the above-mentioned pixel carrier 160, which means the LED chips 114 may be transferred from the bin carrier 140 to the pixel carrier 160 directly.

FIG. 13B and FIG. 14A both show the growth substrate 110 is cut in advance to separate the LED sections 112 from each other, and then the LED sections 112 are transferred to the auxiliary bin carrier 120, but the present disclosure is not limited thereto. In some embodiments of the present disclosure, the cutting of the growth substrate 110 is not needed. Instead, all the LED sections 112 are transfer to another temporary substrate (not shown) in advance, and then, following the step S04, the steps of FIG. 13A or FIG. 14A to transfer the LED sections to the bin carrier 140 or the pixel carrier. In this way, the growth substrate 110 can be recycled. It should be noted that, in this embodiment, the step of removing a single portion of the growth substrate 110 needs to be replaced by the step of removing a single portion of the temporary substrate.

For example, the growth substrate 110 with LED sections 112 can be flipped, and the LED sections 112 are adhered to a first temporary substrate (not shown) in advance. Next, the growth substrate 110 is detached to leave all the LED sections 112 on the first temporary substrate. The first temporary substrate with the LED sections 112 can be cut so that the LED sections 112 are separated from each other before transferring to the auxiliary bin carrier 120 or the bin carrier 140. Briefly, in some embodiments, the growth substrate 110 in FIGS. 13B-13E and FIGS. 14A-14D can be replaced with a first temporary substrate, and all the LED chips 114 are turned upside down.

In another embodiment, all the LED sections 112 on the growth substrate 110 can be flipped and transferred to a first temporary substrate (not shown) in advance, be flipped and transferred again to a second temporary substrate (not shown), and then be cut so that the LED sections 112 are separated from each other. Briefly, in one embodiment, the growth substrate 110 in FIGS. 13B-13E and FIGS. 14A-14D is replaced with the second temporary substrate, but the orientation of all LED chips 114 remains the same.

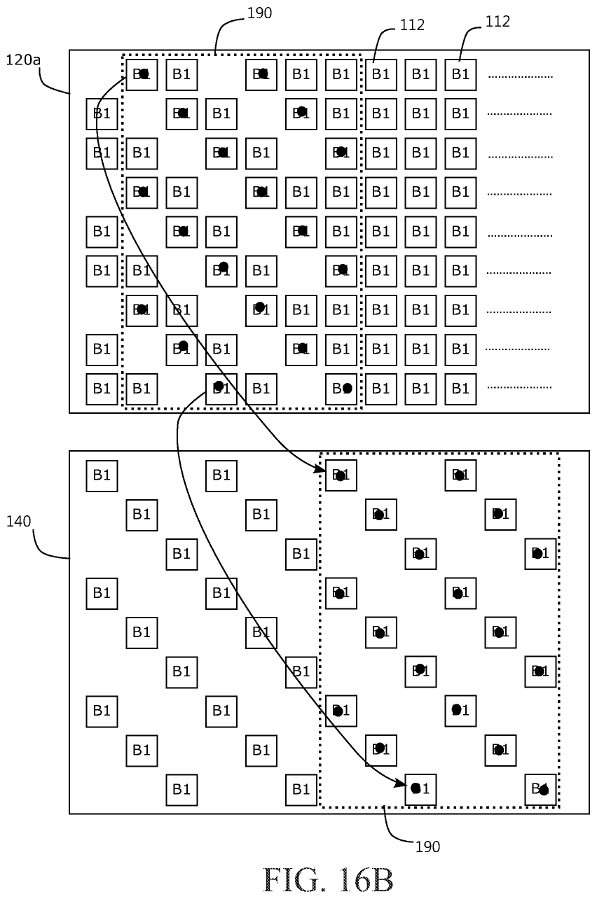

According to an embodiment of the present disclosure, FIGS. 15A-15D illustrate the schematic diagrams showing the steps of transferring the LED sections 112b from a substrate 110′ to a carrier board 170 while the LED sections 112a remain on the substrate 110′. The substrate 110′ may be the growth substrate 110, the first temporary substrate, or the second temporary substrate as above-mentioned. The carrier board 170 may be the auxiliary bin carrier 120, the bin carrier 140, the auxiliary pixel carrier 150, or the pixel carrier 160 as above-mentioned. Each of the first temporary substrate and the second temporary substrate may include a support substrate (not shown) and an adhesive material (not shown) for bonding the LED chips to the support substrate. The support substrate may be glass or sapphire. The adhesive material may be polyimide (PI), butylcyclobutene (BCB), parylene, fluorocarbons, or acrylates.

FIG. 15A is similar to FIG. 12, showing the LED sections 112a and 112b on the display substrate 110′ while each LED section has a plurality of the LED chips 114.

In FIG. 15B, the substrate 110′ of FIG. 15A is flipped and adhered to the carrier board 170 through an adhesive layer 178.

FIG. 15C shows the patterned photoresist layers 172 are formed on the substrate 110′ of FIG. 15B. The photoresist layer 172 covers the LED section 112a but exposes the LED section 112b. FIG. 15C also shows that the laser 174 irradiates the carrier board 170 to selectively conduct the laser lift-off or laser ablation on the LED chip 114 in the LED section 112b. For example, the substrate 110′ is a sapphire substrate, and the laser 174 can penetrate the substrate 110′ so that the nitride-based layer of the GaN-based LED chips 114 in contact with the substrate 110′ is vaporized. Therefore, the LED chips 114 can be detached from the substrate 110′ with stress applied slightly. The photoresist layer 172 may prevent the laser 174 from irradiating the LED chips 114 in the LED section 112a. Therefore, the LED section 112a remains attached to the substrate 110′.

FIG. 15D shows that the substrate 110′ is detached from the carrier board 170. At this time, due to the previous irradiation of the laser 174, the bonding force between the LED chips 114 in the LED section 112b and the substrate 110′ is reduced and is smaller than the bonding force between the LED chips 114 and the adhesive layer 178. Therefore, the LED chips 114 in the LED section 112b can be detached from the substrate 110′ and bonded to the adhesive layer 178 of the carrier board 170. The LED chips 114 in the LED section 112a remain attached to the substrate 110′, as shown in FIG. 15D. In this way, the LED section 112b is transferred to the carrier board 170 while the LED section 112a remains on the substrate 110′.

In another embodiment, the LED sections 112a and 112b are not in direct contact with the adhesive layer 178 but are separated from the adhesive layer 178 by a distance greater than zero, such as 5˜25 μm. After the step of laser lift-off or laser ablation in FIG. 15C and FIG. 15D, the LED section 112b then falls by gravity, and is bonded to the carrier board 170 through the adhesive layer 178. Afterwards, if there is any residual adhesive material on the substrate 110′, it may be removed by etching or plasma irradiation.

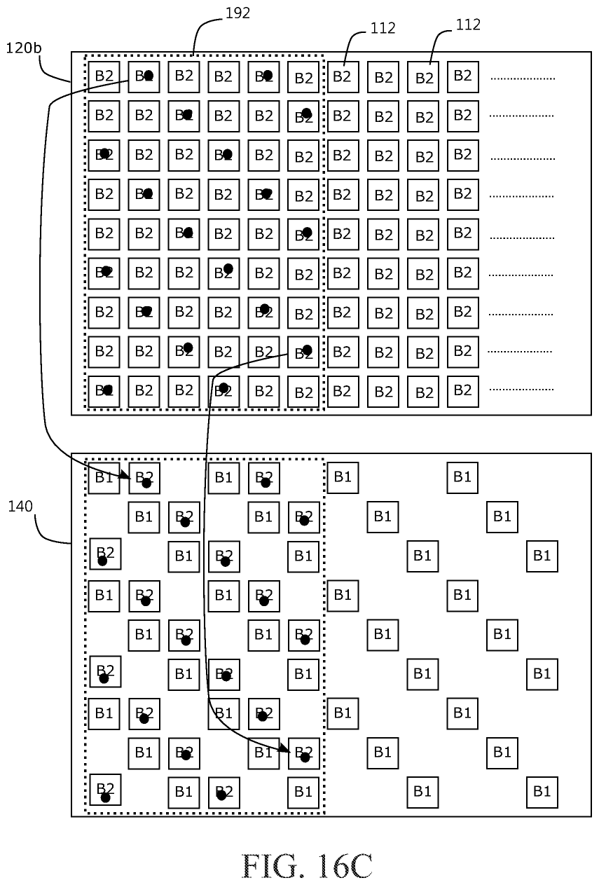

FIGS. 16A-16D illustrate how to transfer the LED sections 112 in a batch to the bin carrier 140 from the auxiliary bin carriers 120a, 120b and 120c.

In FIG. 16A, eighteen LED sections 112 (as the sections marked with black dots in the figure) are picked up by a pick-and-place head 190 at the same time, and these eighteen LED sections are transferred from the auxiliary bin carrier 120a in a batch to the bin carrier 140. There are only LED sections 112 of bin “B1” on the auxiliary bin carrier 120a. The arrows in FIG. 16A illustrate the position movement of two LED sections 112 on the auxiliary bin carrier 120a to the bin carrier 140. In other words, the eighteen LED sections in FIG. 16A are transferred from the auxiliary bin carrier 120a in a batch to the bin carrier 140 according to a picking rule. This picking rule is presented, for example, in the arrangement of the LED sections 112 of the bin carrier 140 in FIG. 16A.

In FIG. 16B, the same pick-and-place head 190 is used, and eighteen LED sections 112 are picked up at once and transferred from the auxiliary bin carrier 120a in a batch to the bin carrier 140 according to the same picking rule. The arrows in FIG. 16B illustrate the position movement of two LED sections 112 on the auxiliary bin carrier 120a to the bin carrier 140. FIG. 16B shows that the picked-up eighteen LED sections 112 are disposed next to the picked-up LED sections shown in FIG. 16A.

By repeating the batch transferring method with the pick-and-place head 190 in FIG. 16A and FIG. 16B, the LED sections 112 of bin “B1” on the auxiliary carrier 120a can be transferred to the bin carrier 140 rapidly and efficiently and disposed on the bin carrier 140 according to the default bin pattern 130 in FIG. 5.

By using different pick-and-place heads and adopting the methods similar to those in FIG. 16A and FIG. 16B, the LED sections 112 of bins “B2” and “B3” can be transferred from the corresponding auxiliary bin carriers and disposed on the bin carrier 140. In FIG. 16C, eighteen LED sections 112 of bin “B2” are picked up by a pick-and-place head 192 at the same time and transferred from the auxiliary bin carrier 120b to the bin carrier 140. There are only LED sections 112 of bin “B2” on the auxiliary bin carrier 120b. In FIG. 16D, eighteen LED sections 112 of bin “B3” are picked up by a pick-and-place head 194 at the same time and transferred from the auxiliary bin carrier 120c to the bin carrier 140. There are only LED sections 112 of bin “B3” on the auxiliary bin carrier 120c. It can be seen from the bin carrier 140 of FIG. 16D that the LED sections 112 of the bins “B1”, “B2” and “B3” have been placed on part of the bin carrier 140. Finally, the bin carrier 140 of FIG. 6 with the default bin pattern 130 can be produced.

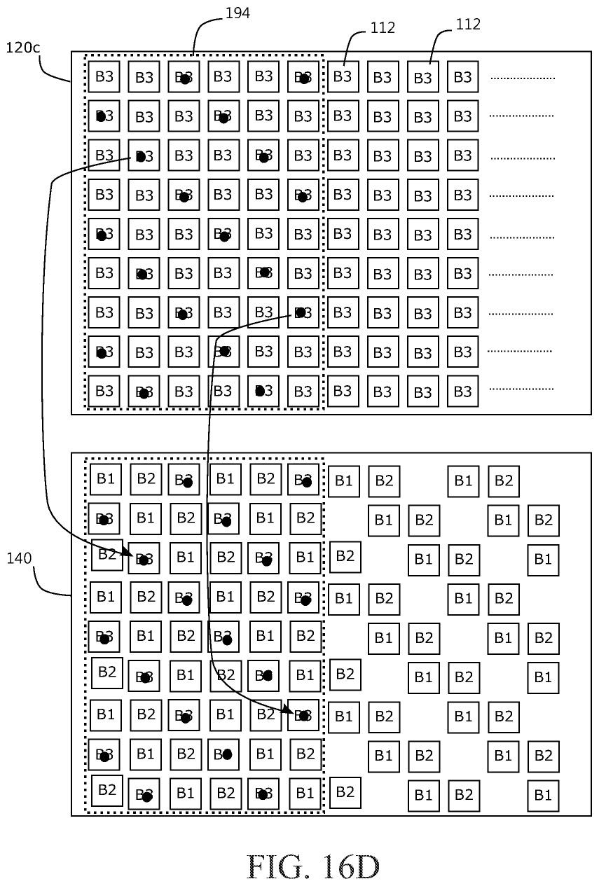

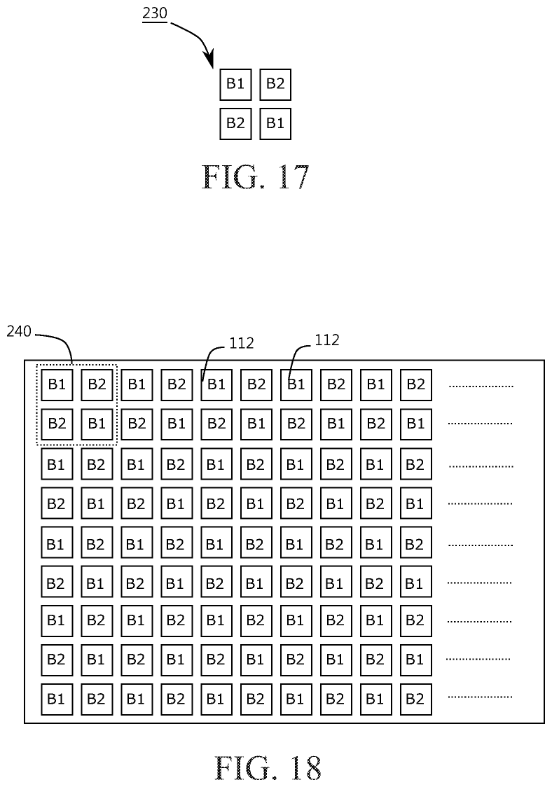

The present disclosure is not limited to the default bin pattern 130 in FIG. 5 and the bin carrier 140 in FIG. 6. FIG. 17 shows another bin pattern 230, and FIG. 18 shows a bin carrier 240 formed according to the bin pattern 230.

In another embodiment, a bin carrier can be formed without a preset bin pattern. There are no repeating bin patterns on this bin carrier. There are several LED sections on the bin carrier, and each LED section has a plurality of LED chips arranged in array. Each LED section is assigned to a bin based on a test result. The number of LED sections of each bin on the bin carrier has a preset fixed bin ratio. For example, the B1 bin ratio is the number of LED sections of bin B1 divided by the number of all the LED sections on the bin carrier. In a bin carrier according to the present disclosure, the B1 bin ratio is ⅓, the B2 bin ratio is ⅓, and the B3 bin ratio is also ⅓.

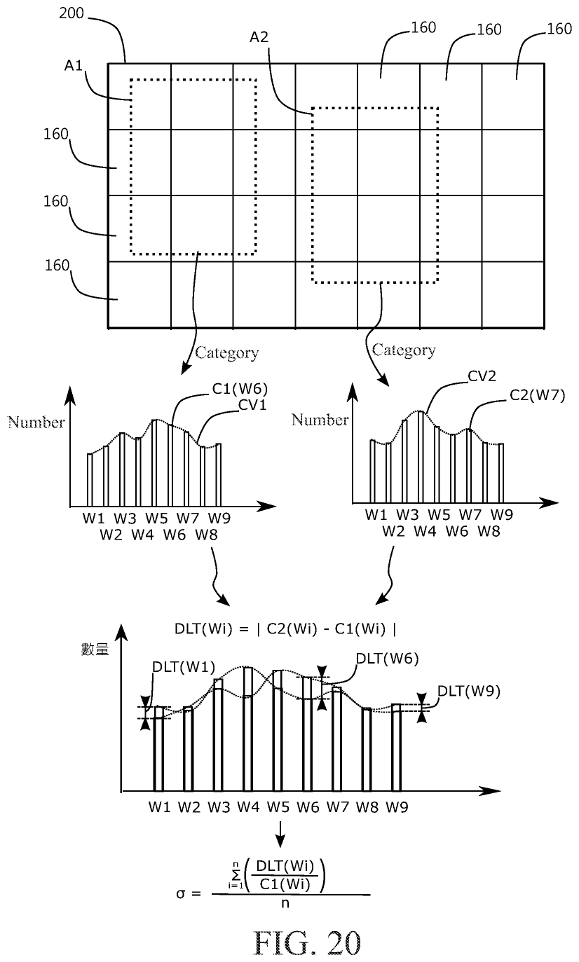

FIG. 20 shows the relation between the display 200 and the variability σ. According to an embodiment, the display 200 is composed of a plurality of pixel carriers 160, and the LED chips of each pixel carrier 160 are from a plurality of bin carriers with the same bin ratio, as shown in FIG. 20. Therefore, the variability σ of the optoelectronic property distribution curve of the single-color LED chips between the rectangular sections A1 and A2 at different positions in the display 200 is small, for example, σ is less than 30%, 25%, 15%, 10%, or 8%. In that case, the visual perception of human eye is less likely to perceive the color discontinuity or color unevenness among different pixel carriers 160. In an embodiment, the rectangular sections A1 and A2 in the display 200 including at least 10000 LED chips with the same color. The distribution curve of optoelectronic property can be obtained by measuring the photoelectric property of any row, any column, or all single-color LED chips. An exemplary calculation of the variability is as follows, wherein the rectangular section A1 has a distribution curve of optoelectronic property CV1, and the rectangular section A2 has a distribution curve of optoelectronic property CV2. The distribution curve of optoelectronic property CV1 is a relationship diagram between different bin wavelengths W1, W2, W3 . . . Wn and the number of LED chips Cl(W1), Cl(W2), Cl(W3) . . . C1(Wn). The distribution curve of optoelectronic property CV2 is a relationship diagram between different bin wavelengths W1, W2, W3 . . . Wn and the number of LED chips Cl(W1), Cl(W2), Cl(W3) . . . C1(Wn). The variability

$$σ = \frac{{\sum }_{i = 1}^{n} \frac{\vert {C}_{2} ( Wi ) - {C}_{1} ( Wi ) \vert}{{C}_{1} ( Wi )}}{n} .$$

The smaller the variability σ is, the closer the distribution curves of optoelectronic property CV1 and CV2 are, and the more similar the rectangular sections A1 and A2 are in terms of optoelectronic property.

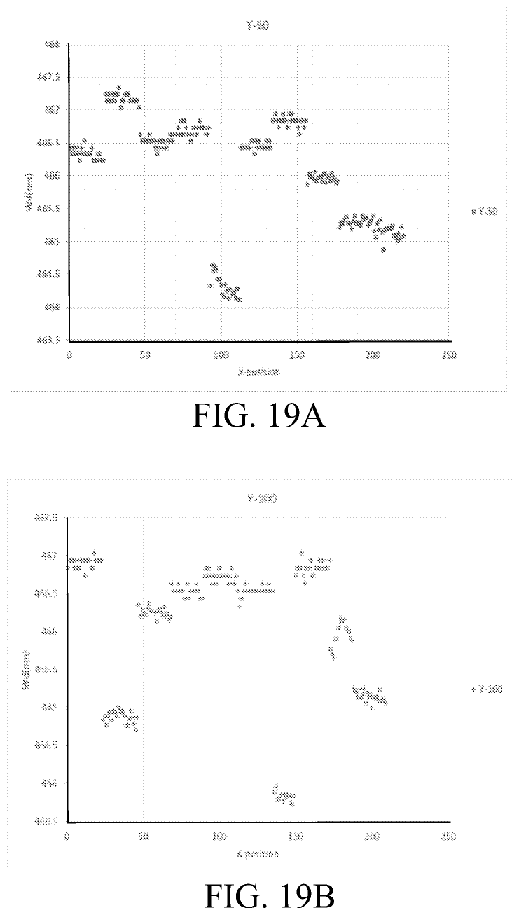

According to the implementation of the present disclosure, if the relationship between the peak wavelength and the position of the LED chips is drawn for a bin carrier without a preset bin pattern similar to FIG. 10 or 11, there can be also many obviously discontinuous wavelength changes, but probably no repeatable change varied with position. FIG. 19A and FIG. 19B show the relationship between the peak wavelength and the position of two rows of LED chips on a bin carrier. It can be found out that the LED chips belonging to the same LED section have similar peak wavelengths, while the LED chips belonging to different LED sections may have larger emission wavelength differences between each other.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An LED arrangement method, comprising:
providing a plurality of first LED sections and a plurality of second LED sections commonly located on a substrate; and
transferring the plurality of first LED sections and the plurality of second LED sections to a bin carrier to form an array of sections comprising a plurality of columns and a plurality of rows;
wherein each of the plurality of first LED sections comprises a plurality of first LED chips, and the plurality of first LED chips, as a whole, belong to a first bin,
wherein each of the plurality of second LED sections comprises a plurality of second LED chips, and the plurality of second LED chips, as a whole, belong to a second bin,
wherein each of the plurality of columns comprises one of the plurality of first LED sections and one of the plurality of second LED sections, and
wherein each of the plurality of rows comprises one of the plurality of first LED sections and one of the plurality of second LED sections.

2. The LED arrangement method as claimed in claim 1, wherein the first bin is determined by an overall optoelectronic property of the plurality of first LED chips, wherein the overall optoelectronic property comprises peak wavelength, illuminance intensity level, or chromaticity scale.

3. The LED arrangement method as claimed in claim 1, wherein the plurality of first LED sections and the plurality of second LED sections are arranged into the array of sections according to a preset bin pattern.

4. The LED arrangement method as claimed in claim 1, wherein a ratio of a number of the plurality of first LED sections and a number of the plurality of second LED sections is substantially the same in any two columns of the plurality of the columns or in any two rows of the plurality of the rows.

5. The LED arrangement method as claimed in claim 1, wherein the transferring step comprises:
transferring the plurality of first LED sections to a first auxiliary bin carrier; and
transferring the plurality of second LED sections to a second auxiliary bin carrier.

6. The LED arrangement method as claimed in claim 5, wherein the transferring step further comprises:
transferring the plurality of first LED sections on the first auxiliary bin carrier and the plurality of second LED sections on the second auxiliary bin carrier to the bin carrier to form the array of sections.

7. The LED arrangement method as claimed in claim 1, wherein the transferring step is pick-and-place, laser lift-off, laser ablation, or a combination thereof.

8. The LED arrangement method as claimed in claim 1,
wherein the plurality of first LED chips and the plurality of second LED chips are arranged into a plurality of sub-columns and a plurality of sub-rows in the array of sections,
wherein an optoelectronic property curve of the plurality of the first and second LED chips is measurable along one of the sub-columns or one of the sub-rows,
wherein the optoelectronic property curve has one discontinuous change, and the discontinuous change is approximately located at a junction of two adjacent sections in the array of sections.

9. The LED arrangement method as claimed in claim 1, wherein the substrate comprises a support substrate and an adhesive material on the support substrate.

10. The LED arrangement method as claimed in claim 1, wherein the transferring step comprises forming a patterned light blocking layer on a side of the substrate opposite to the plurality of the first and second LED sections.

11. An LED arrangement device, comprising:
a carrier; and
a plurality of LED chips on the carrier and is arranged in an array with rows and columns;
wherein each of the plurality of LED chips has a peak wavelength, and, in one of the rows or columns, a distribution of the peak wavelengths of the LED chips has a regular change.

12. The LED arrangement device according to claim 11, wherein the regular change comprises a repetitive stair-like pattern.

13. The LED arrangement device according to claim 12, wherein the repetitive stair-like pattern comprises ascending stair-like pattern, descending stair-like pattern, or a combination thereof.

14. The LED arrangement device according to claim 11, wherein the plurality of LED chips is adhered to the carrier.

15. The LED arrangement device according to claim 14, wherein the carrier comprises silicon, glass, sapphire, silicon carbide, thermal release tape, UV release tape, chemical release tape, heat resistant tape, tape with a dielectric release layer, or blue tape.

16. The LED arrangement device according to claim 14, wherein each of the plurality of LED chips comprises a first semiconductor layer, an active layer, a second semiconductor layer, and two electrodes electrically connecting the first semiconductor layer and the second semiconductor layer respectively.

17. The LED arrangement device according to claim 16, wherein each of the plurality of LED chip is adhered to the carrier through the two electrodes.

18. The LED arrangement device according to claim 16, wherein the electrodes of each of the plurality of LED chip face away from the carrier.

19. The LED arrangement device according to claim 16, wherein each of the plurality of LED chip further comprises a growth substrate.

20. The LED arrangement device according to claim 19, wherein the growth substrate contacts the carrier.
